(19) United States
(12) Patent Application Publication
(10) Pub. No.: US 2025/0176313 A1
(43) Pub. Date: May 29, 2025

(54) LIGHT EMITTING DEVICE, ELECTRONIC APPARATUS, AND METHOD OF MANUFACTURING LIGHT EMITTING DEVICE

(71) Applicant: SEIKO EPSON CORPORATION, Tokyo (JP)

(72) Inventor: Shunsuke ISHIZAWA, TOKYO-TO (JP)

(73) Assignee: SEIKO EPSON CORPORATION, Tokyo (JP)

(21) Appl. No.: 18/961,500

(22) Filed: Nov. 27, 2024

(30) Foreign Application Priority Data
Nov. 29, 2023 (JP) 2023-201454

(51) Int. Cl. H10H 20/811; H10H 20/01; H10H 20/832; H10H 20/855

(52) U.S. Cl. CPC H10H 20/811; H10H 20/032; H10H 20/832; H10H 20/855

(57) ABSTRACT

A light emitting device includes a substrate, a plurality of column portions, a first semiconductor layer of a first conductivity type, a first pixel electrode being provided between a plurality of first column portions of the plurality of column portions and the substrate, a second pixel electrode being provided between a plurality of second column portions of the plurality of column portions and the substrate, and a common electrode being provided on a side of the first semiconductor layer opposite to the substrate, wherein each of the plurality of column portions includes a second semiconductor layer of a second conductivity type different from the first conductivity type, a third semiconductor layer of the first conductivity type, the third semiconductor layer being provided between the first semiconductor layer and the second semiconductor layer, and a quantum well layer being provided between the second semiconductor layer and the third semiconductor layer.

The present application is based on, and claims priority from JP Application Serial Number 2023-201454, filed Nov. 29, 2023, the disclosure of which is hereby incorporated by reference herein in its entirety.

### BACKGROUND

### 1. Technical Field

The present disclosure relates to a light emitting device, an electronic apparatus, and a method of manufacturing a light emitting device.

### 2. Related Art

A light emitting element such as a light emitting diode (LED) is applied to a light source of a display device and the like.

For example, JP-A-2021-82687 describes that, in an image display device in which micro light emitting elements are arranged in an array, the micro light emitting element includes an excitation light emitting element that generates excitation light, a reflection wall surrounding the excitation light emitting element, and a wavelength conversion material arranged on the inside of the reflection wall.

In the image display device described above, the excitation light emitting elements are required to be integrated densely. In the image display device described in JP-A-2021-82687, the reflection wall is provided between the adjacent excitation light emitting elements, and hence it is difficult to reduce a distance between the adjacent excitation light emitting elements.

### SUMMARY

According to one aspect of the present disclosure, a light emitting device includes a substrate, a plurality of column portions, a first semiconductor layer of a first conductivity type, the first semiconductor layer being provided to overlap with the plurality of column portions, a first pixel electrode being provided between a plurality of first column portions of the plurality of column portions and the substrate, a second pixel electrode being provided between a plurality of second column portions of the plurality of column portions and the substrate and being separated from the first pixel electrode, and a common electrode being provided on a side of the first semiconductor layer opposite to the substrate, wherein each of the plurality of column portions includes a second semiconductor layer of a second conductivity type different from the first conductivity type, a third semiconductor layer of the first conductivity type, the third semiconductor layer being provided between the first semiconductor layer and the second semiconductor layer, and a quantum well layer being provided between the second semiconductor layer and the third semiconductor layer.

According to one aspect of the present disclosure, an electronic apparatus includes the light emitting device according to the one aspect.

According to one aspect of the present disclosure, a method of manufacturing a light emitting device includes forming a first semiconductor layer of a first conductive type at a first substrate, forming a plurality of column portions at the first semiconductor layer, forming a first pixel electrode over a plurality of first column portions of the plurality of column portions and forming a second pixel electrode over a plurality of second column portions of the plurality of column portions, joining, to a second substrate, a structure body including the first substrate, the first semiconductor layer, the plurality of column portions, the first pixel electrode, and the second pixel electrode while a side of the structure body that is close to the first pixel electrode and the second pixel electrode faces the second substrate, removing the first substrate to expose the first semiconductor layer, and forming a common electrode at the first semiconductor layer, wherein, during the formation of the plurality of column portions, the plurality of column portions are formed, the plurality of column portions including a second semiconductor layer of a second conductivity type different from the first conductivity type, a third semiconductor layer of the first conductivity type, and a quantum well layer being provided between the second semiconductor layer and the third semiconductor layer.

### BRIEF DESCRIPTION OF THE DRAWINGS

FIG. 1 is a cross-sectional view schematically illustrating a light emitting device according to an embodiment.

FIG. 2 is a plan view schematically illustrating the light emitting device according to the embodiment.

FIG. 3 is a flowchart for describing a method of manufacturing the light emitting device according to the embodiment.

FIG. 4 is a cross-sectional view schematically illustrating a manufacturing step of the light emitting device according to the embodiment.

FIG. 5 is a cross-sectional view schematically illustrating the manufacturing step of the light emitting device according to the embodiment.

FIG. 6 is a cross-sectional view schematically illustrating the manufacturing step of the light emitting device according to the embodiment.

FIG. 7 is a cross-sectional view schematically illustrating the manufacturing step of the light emitting device according to the embodiment.

FIG. 8 is a cross-sectional view schematically illustrating the manufacturing step of the light emitting device according to the embodiment.

FIG. 9 is a cross-sectional view schematically illustrating the manufacturing step of the light emitting device according to the embodiment.

FIG. 10 is a cross-sectional view schematically illustrating a light emitting device according to a first modification example of the embodiment.

FIG. 11 is a cross-sectional view schematically illustrating a light emitting device according to the second modification example of the embodiment.

FIG. 12 is a plan view schematically illustrating the light emitting device according to the second modification example of the embodiment.

FIG. 13 is a view schematically illustrating a projector according to the embodiment.

FIG. 14 is a plan view schematically illustrating a display according to the embodiment.

FIG. 15 is a cross-sectional view schematically illustrating the display according to the embodiment.

FIG. 16 is a perspective view schematically illustrating a head-mounted display according to the embodiment.

FIG. 17 is a view schematically illustrating an image forming device and a light guiding device of the head-mounted display according to the embodiment.

### DESCRIPTION OF EMBODIMENTS

A preferred embodiment of the present disclosure is described in detail below with reference to the drawings. Note that the embodiment described below do not unduly limit the content of the present disclosure described in the claims. In addition, not all the configurations described below are essential constituent elements of the present disclosure.

### 1. Light Emitting Device

### 1.1. Configuration

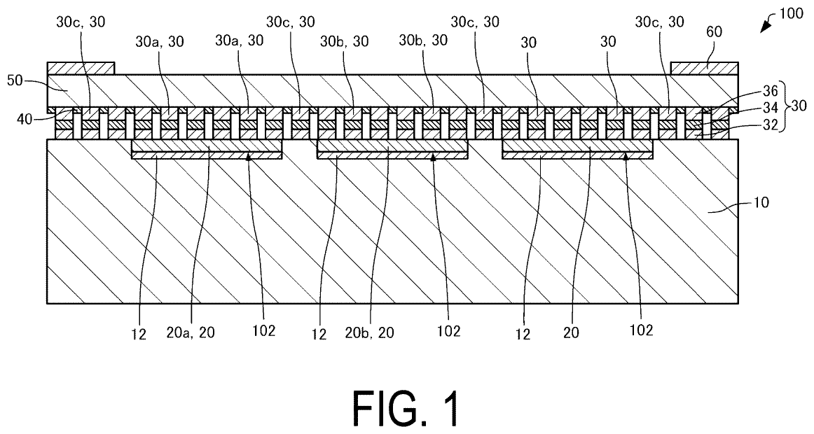

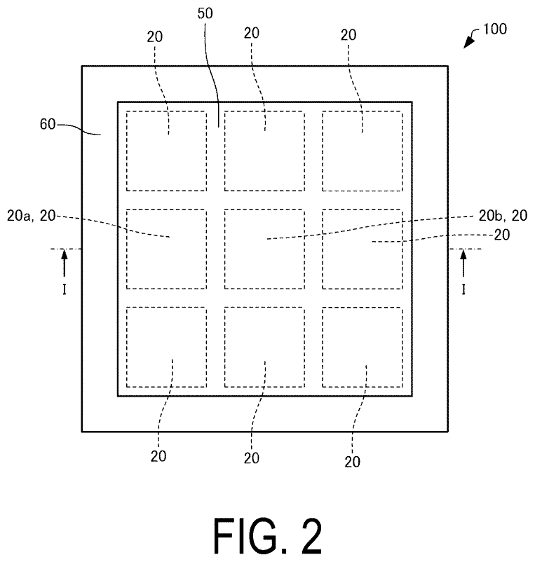

First, a light emitting device according to an embodiment is described with reference to the drawings. FIG. 1 is a cross-sectional view schematically illustrating a light emitting device 100 according to the embodiment. FIG. 2 is a plan view schematically illustrating the light emitting device 100 according to the embodiment. Note that FIG. 1 is a cross-sectional view taken along the line I-I in FIG. 2.

As illustrated in FIG. 1 and FIG. 2, for example, the light emitting device 100 includes a driving substrate 10, a pixel electrode 20, a column portion 30, a mask layer 40, a first semiconductor layer 50, and a common electrode 60.

For example, the driving substrate 10 is a Si substrate to which a driving circuit is provided. The driving circuit is a circuit for driving the light emitting device 100. For example, the driving circuit is configured by an integrated circuit (IC). The driving circuit includes a pad electrode 12. The material of the pad electrode 12 is metal. A plurality of pad electrodes 12 are provided corresponding to a plurality of pixel electrodes 20.

As illustrated in FIG. 1, the pixel electrode 20 is provided at the driving substrate 10. The pixel electrode 20 is provided between the driving substrate 10 and the plurality of column portions 30. The pixel electrode 20 is provided at the pad electrode 12. The pixel electrode 20 is electrically coupled to the driving circuit and a second semiconductor layer 32 of the column portion 30. For example, the material of the pixel electrode 20 is metal. Specifically, the pixel electrode 20 is configured by a titanium layer, an aluminum layer, or a laminate body thereof. The pixel electrode 20 is one electrode for injecting a current into a quantum well layer 34. The pixel electrode 20 reflects light generated at the quantum well layer 34 of the column portion 30 to the first semiconductor layer 50 side.

The plurality of the pixel electrodes 20 are provided. In the example illustrated in FIG. 2, the plurality of pixel electrodes 20 are arrayed in a matrix. The plurality of pixel electrodes 20 are separated from each other. For example, the planar shape of the pixel electrode 20 is a rectangular shape. A first pixel electrode 20a and a second pixel electrode 20b of the plurality of pixel electrodes 20 are adjacent to each other. The pixel electrode 20, the column portion 30, the first semiconductor layer 50, and the common electrode 60 configure a plurality of light emitting elements 102. For example, the light emitting element 102 is a light emitting diode (LED).

As illustrated in FIG. 1, the column portion 30 is provided between the driving substrate 10 and the first semiconductor layer 50. The column portion 30 is also called, for example, a nanocolumn, a nanowire, a nanorod, or a nanopillar. For example, the planar shape of the column portion 30 is a polygon such as a regular hexagon or a circle.

The diameter of the column portion 30 is, for example, 50 nm or more and 500 nm or less, and may be 100 nm or more and 200 nm or less. With the column portion 30 having a diameter of 500 nm or less, the quantum well layer 34 of high-quality crystal can be obtained, and distortion in the quantum well layer 34 can be reduced.

Note that the “diameter of the column portion 30” is a diameter when the planar shape of the column portion 30 is a circle, and is a diameter of the minimum inclusion circle when the planar shape of the column portion 30 is a shape other than a circle. For example, when the planar shape of the column portion 30 is a polygon, the diameter of the column portion 30 is the diameter of the smallest circle that includes the polygon therein. When the planar shape of the column portion 30 is an ellipse, the diameter of the column portion 30 is the diameter of the smallest circle that includes the ellipse therein.

A plurality of column portions 30 are provided. The plurality of column portions 30 are separated from each other. In the illustrated example, there is a gap between the adjacent column portions 30. Although not illustrated in the drawing, a space between the adjacent column portions 30 may be filled with an insulating layer. An interval between the adjacent column portions 30 is, for example, 1 nm or more and 500 nm or less. The plurality of column portions 30 are arrayed at a predetermined pitch in a predetermined direction in plan view. The plurality of column portions 30 are arrayed at the predetermined pitch in the predetermined direction as viewed in a stacking direction of the second semiconductor layer 32 and the quantum well layer 34. The plurality of column portions 30 are arrayed in, for example, a regular triangular lattice pattern or a square lattice pattern. The diameter and the pitch of the plurality of column portions 30 are designed such that the photonic crystal formed thereby prevents light of the emission wavelength from propagating in the in-plane direction and instead extracts it in the vertical direction.

Note that the “pitch of the column portions 30” is a distance between the centers of the adjacent column portions 30 in the predetermined direction. The “center of the column portion 30” is a center of a circle when the planar shape of the column portion 30 is a circle, and is a center of the minimum inclusion circle when the planar shape of the column portion 30 is a shape other than a circle. For example, when the planar shape of the column portion 30 is a polygon, the center of the column portion 30 is the center of the smallest circle that includes the polygon therein. When the planar shape of the column portion 30 is an ellipse, the center of the column portion 30 is the center of the smallest circle that includes the ellipse therein.

A first column portion 30a of the plurality of column portions 30 is provided at the first pixel electrode 20a. The first column portion 30a is provided between the first pixel electrode 20a and the first semiconductor layer 50. The first column portion 30a protrudes upward from the first pixel electrode 20a. The first column portion 30a overlaps with the first pixel electrode 20a in plan view. The first column portion 30a is provided to the driving substrate 10 via the first pixel electrode 20a. A plurality of first column portions 30a are provided. The first pixel electrode 20a is provided between the plurality of first column portions 30a and the driving substrate 10.

A second column portion 30b of the plurality of column portions 30 is provided at the second pixel electrode 20b. The second column portion 30b is provided between the second pixel electrode 20b and the first semiconductor layer 50. The second column portion 30b protrudes upward from the second pixel electrode 20b. The second column portion 30b overlaps with the second pixel electrode 20b in plan view. The second column portion 30b is provided to the driving substrate 10 via the first pixel electrode 20a. A plurality of second column portions 30b are provided. The second pixel electrode 20b is provided between the plurality of second column portions 30b and the driving substrate 10.

A third column portion 30c of the plurality of column portions 30 is not provided at the pixel electrode 20. The third column portion 30c is provided at the driving substrate 10 via an insulating layer (for example, SiO₂), which is omitted in illustration. The insulating layer is provided at a region of the driving substrate 10, in which the pixel electrode 20 is not provided. Thus, the third column portion 30c is insulated from the driving substrate 10. Further, instead of providing the insulating layer between the third column portion 30c and the driving substrate 10 as described above, the third column portion 30c and the driving substrate 10 may be in a floating state. A plurality of third column portions 30c are provided. The third column portion 30c is provided between the adjacent pixel electrodes 20 in plan view. The third column portion 30c is provided between the first pixel electrode 20a and the second pixel electrode 20b in plan view. The plurality of third column portions 30c surround the plurality of first column portions 30a in plan view. Further, the plurality of third column portions 30c surround the plurality of second column portions 30b in plan view. The plurality of third column portions 30c surround the plurality of pixel electrodes 20 in plan view. The pitch of the plurality of first column portions 30a, the pitch of the plurality of second column portions 30b, and the pitch of the plurality of third column portions 30c are the same.

The column portion 30 includes the second semiconductor layer 32, the quantum well layer 34, and the third semiconductor layer 36. The second semiconductor layer 32, the quantum well layer 34, and the third semiconductor layer 36 are, for example, a group III nitride semiconductor and have a wurtzite crystal structure.

The second semiconductor layer 32 is provided between the driving substrate 10 and the quantum well layer 34. The second semiconductor layer 32 is a semiconductor layer of a second conductivity type different from the first conductivity type. The second conductivity type is, for example, a p-type. The second semiconductor layer 32 is, for example, a p-type GaN layer doped with Mg.

The quantum well layer 34 is provided at the second semiconductor layer 32. The quantum well layer 34 is provided between the second semiconductor layer 32 and the third semiconductor layer 36. The quantum well layer 34 generates light when a current is injected thereinto. A current is injected into the quantum well layer 34 of the column portion 30 overlapping with the pixel electrode 20 in plan view. Thus, the quantum well layer 34 of the column portion 30 overlapping with the pixel electrode 20 in plan view generates light. Meanwhile, a current is not injected into the quantum well layer 34 of the third column portion 30c that does not overlap with the pixel electrode 20 in plan view. Thus, the quantum well layer 34 of the third column portion 30c does not generate light.

The quantum well layer 34 includes, for example, a well layer and a barrier layer. The well layer and the barrier layer are i-type semiconductor layers which are not doped with impurities intentionally. The well layer is, for example, an InGaN layer. The barrier layer is, for example, a GaN layer. The quantum well layer 34 has a multiple quantum well (MQW) structure configured by the well layer and the barrier layer.

Note that the numbers of the well layers and the barrier layers configuring the quantum well layer 34 are not particularly limited. For example, only one well layer may be provided, and in this case, the quantum well layer 34 has a single quantum well (SQW) structure. Further, although not illustrated in the drawing, an electron blocking layer formed of a p-type AlGaN layer may be provided between the second semiconductor layer 32 and the quantum well layer 34.

The third semiconductor layer 36 is provided at the quantum well layer 34. The third semiconductor layer 36 is provided between the quantum well layer 34 and the first semiconductor layer 50. The third semiconductor layer 36 is provided between the second semiconductor layer 32 and the first semiconductor layer 50. The third semiconductor layer 36 is a semiconductor layer of the first conductivity type. The first conductivity type is, for example, an n-type. The third semiconductor layer 36 is, for example, an n-type GaN layer doped with Si. The second semiconductor layer 32 and the third semiconductor layer 36 are clad layers having a function of confining light in the quantum well layer 34.

In the light emitting device 100, a pin diode is configured by the second semiconductor layer 32 of the p-type, the quantum well layer 34 which is the i-type and not intentionally doped with impurities, and the third semiconductor layer 36 of the n-type. In the light emitting device 100, when a forward bias voltage of the pin diode is applied between the pixel electrode 20 and the common electrode 60 by the driving circuit of the driving substrate 10, a current is injected into the quantum well layer 34, and electrons and positive holes are recombined in the quantum well layer 34. This recombination causes light emission. Due to the effect of the photonic crystal by the plurality of column portions 30, light generated at the quantum well layer 34 does not propagate in a lateral direction, but is emitted in an up-and-down direction, in other words, a vertical direction. The pixel electrode 20 reflects light, which is emitted downward, upward.

The mask layer 40 is provided to the periphery of the column portion 30. The mask layer 40 is provided below the first semiconductor layer 50. For example, the thickness of the mask layer 40 is 1 nm or more and 10 nm or less, and may be 2 nm or more and 8 nm or less. When the thickness of the mask layer 40 is 10 nm or less, the absorption of the light in the mask layer 40 can be reduced. For example, the mask layer 40 is a Ti layer, a TiO₂ layer, or an SiO₂ layer. The mask layer 40 is a mask for growing the column portion 30.

The first semiconductor layer 50 is provided at the plurality of column portions 30. The first semiconductor layer 50 is provided on a side of the plurality of column portions 30 opposite to the driving substrate 10. The first semiconductor layer 50 is provided over the plurality of column portions 30. The first semiconductor layer 50 is provided between the plurality of column portions 30 and the common electrode 60. The first semiconductor layer 50 is provided to overlap with the plurality of column portions 30. The first semiconductor layer 50 is a semiconductor layer of the first conductivity type. The first semiconductor layer 50 is, for example, an n-type GaN layer doped with Si.

The common electrode 60 is provided at the first semiconductor layer 50. The common electrode 60 is provided on a side of the first semiconductor layer 50 opposite to the driving substrate 10. For example, as illustrated in FIG. 2, the common electrode 60 does not overlap with the pixel electrode 20 in plan view. For example, the common electrode 60 surrounds the plurality of pixel electrodes 20 in plan view.

The common electrode 60 is electrically coupled to the third semiconductor layer 36 of the column portion 30 via the first semiconductor layer 50. The first semiconductor layer 50 may be in ohmic contact with the common electrode 60. Although not illustrated in the drawing, through wire bonding or the like, the common electrode 60 is electrically coupled to the driving circuit provided to the driving substrate 10. The common electrode 60 is formed by, for example, stacking a Pd layer, a Pt layer, a Ni layer, and an Au layer in the stated order from the first semiconductor layer 50 side, or is a single metal layer. The common electrode 60 is the other electrode for injecting a current into the quantum well layer 34.

While the quantum well layer 34 described above is InGaN based, the quantum well layer 34 may be made of various materials capable of emitting light when a current is injected thereinto, depending on the wavelength of light to be emitted. For example, semiconductor materials such as an AlGaN based, AlGaAs based, InGaAs based, InGaAsP based, InP based, GaP based, and AlGaP based materials may be used.

Although the description is given above on the assumption that the first conductivity type is an n-type and the second conductivity type is a p-type, the first conductivity type may be a p-type and the second conductivity type may be an n-type.

### 1.2. Operations and Effects

The light emitting device 100 includes the driving substrate 10, the plurality of column portions 30, the first semiconductor layer 50 of the first conductivity type that is provided to overlap with the plurality of column portions 30, the first pixel electrode 20a that is provided between the plurality of first column portions 30a of the plurality of column portions 30 and the driving substrate 10, the second pixel electrode 20b that is provided between the plurality of second column portions 30b of the plurality of column portions 30 and the driving substrate 10 and is separated from the first pixel electrode 20a, and the common electrode 60 that is provided on a side of the first semiconductor layer 50 opposite to the driving substrate 10. Each of the plurality of column portions 30 includes the second semiconductor layer 32 of the second conductivity type different from the first conductivity type, the third semiconductor layer 36 of the first conductivity type that is provided between the first semiconductor layer 50 and the second semiconductor layer 32, and the quantum well layer 34 that is provided between the second semiconductor layer 32 and the third semiconductor layer 36.

Thus, in the light emitting device 100, due to the effect of the photonic crystal by the plurality of column portions 30, highly directional light can be emitted in the vertical direction. With this, high efficiency can be achieved without providing a reflection wall between the first pixel electrode 20a and the second pixel electrode 20b. Therefore, the distance between the first pixel electrode 20a and the second pixel electrode 20b can be reduced. Thus, the light emitting elements 102 can be integrated densely.

In the light emitting device 100, the common electrode 60 does not overlap with the first pixel electrode 20a and the second pixel electrode 20b in plan view. Thus, in the light emitting device 100, the common electrode 60 can lower the possibility of absorbing light generated at the quantum well layer 34.

In the light emitting device 100, it is assumed that the material of the first pixel electrode 20a and the second pixel electrode 20b is metal having high reflectance with respect to a wavelength of emitted light. For example, the material is Al. Thus, in the light emitting device 100, the first pixel electrode 20a can reflect light generated at the quantum well layer 34 of the first column portion 30a. Further, the second pixel electrode 20b can reflect light generated at the quantum well layer 34 of the second column portion 30b.

In the light emitting device 100, the third column portion 30c of the plurality of column portions 30 is provided between the first pixel electrode 20a and the second pixel electrode 20b in plan view. In this manner, in the light emitting device 100, in order to achieve element isolation between the light emitting element 102 including the first pixel electrode 20a and the light emitting element 102 including the second pixel electrode 20b, the third column portion 30c that is provided between the first pixel electrode 20a and the second pixel electrode 20b in plan view is not removed. Thus, the structure of the light emitting device 100 can be simplified.

### 2. Method of Manufacturing Light Emitting Device

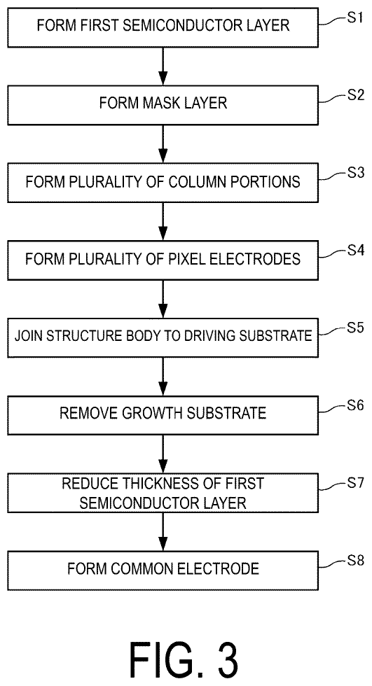

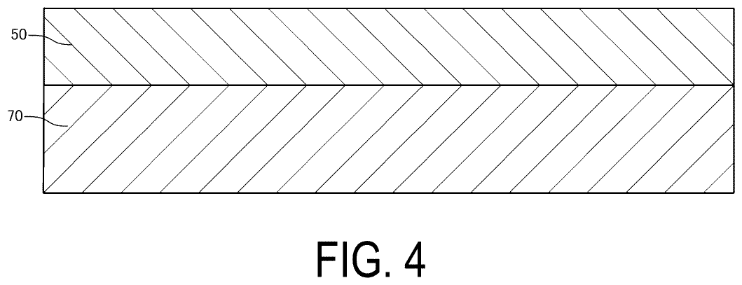

Next, a method of manufacturing the light emitting device 100 according to the embodiment is described with reference to the drawings. FIG. 3 is a flowchart for describing the method of manufacturing the light emitting device 100 according to the embodiment. FIG. 4 to FIG. 9 are cross-sectional views schematically illustrating manufacturing steps of the light emitting device 100 according to the embodiment.

As illustrated in FIG. 3 and FIG. 4, the first semiconductor layer 50 is formed at a growth substrate 70 (Step S1). Specifically, the first semiconductor layer 50 is epitaxially grown at the growth substrate 70. Examples of the epitaxial growth method include a metal organic chemical vapor deposition (MOCVD) method and a molecular beam epitaxy (MBE) method. For example, the growth substrate 70 is a sapphire substrate, an Si substrate, or an SiC substrate. The upper surface of the growth substrate 70 is, for example, a c surface.

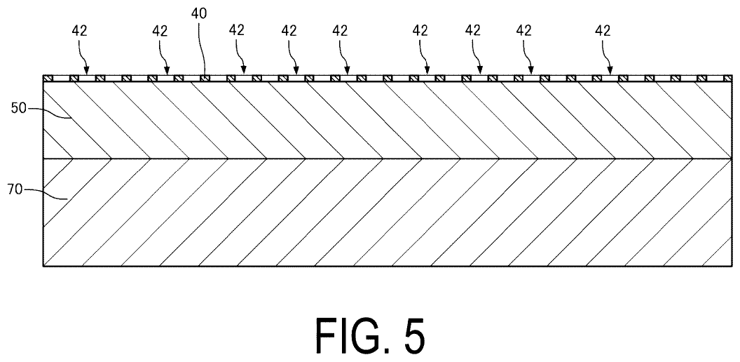

As illustrated in FIG. 5, the mask layer 40 is formed at the first semiconductor layer 50 (Step S2). For example, the mask layer 40 is formed by a chemical vapor deposition (CVD) method, an electron beam (EB) deposition method, or a sputtering method. Next, the mask layer 40 is subjected to patterning to form a plurality of opening portions 42. For example, the planar shape of the opening portion 42 is a circle. For example, the patterning is performed by resist patterning using electron beam lithography and dry etching. Note that the patterning may also be performed using photolithography or nanoimprint lithography. In the patterning, a lift-off method may be used instead of etching.

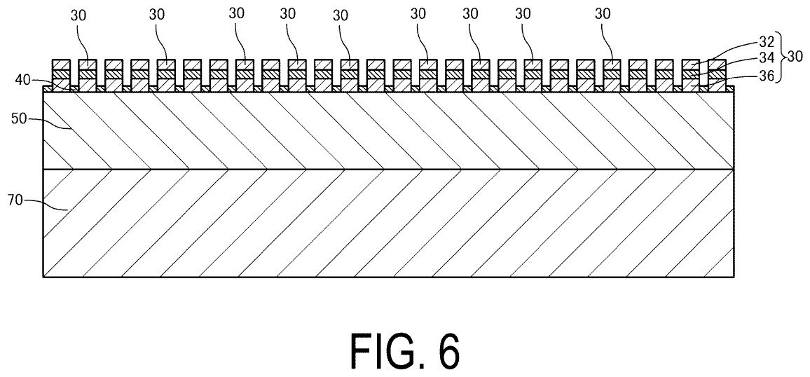

As illustrated in FIG. 6, the plurality of column portions 30 are formed at the first semiconductor layer 50 (Step S3). Specifically, while using the mask layer 40 as a mask, the second semiconductor layer 32, the quantum well layer 34, and the third semiconductor layer 36 are epitaxially grown in the stated order at the first semiconductor layer 50. For example, the epitaxial growth is performed by the MBE method using radio frequency (RF) plasma as a nitrogen material source. By using appropriate conditions for a substrate temperature and a material irradiation amount, crystal deposition on the mask layer 40 can be suppressed, and crystal growth can selectively be promoted in the opening portion 42.

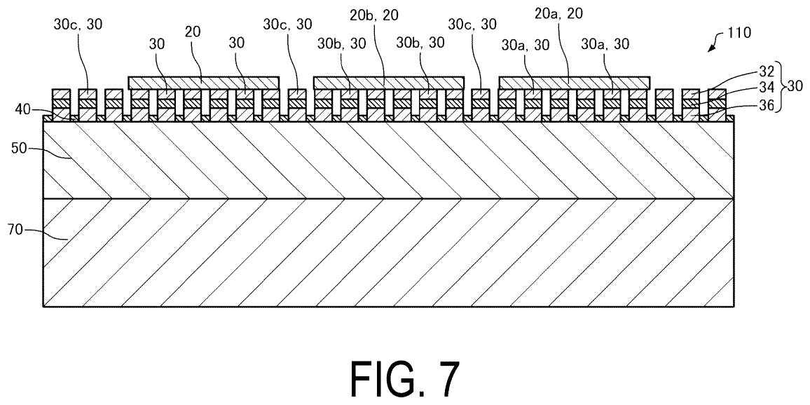

As illustrated in FIG. 7, the plurality of pixel electrodes 20 are formed at the plurality of column portions 30 (Step S4). In this step, the first pixel electrode 20a is formed over the plurality of first column portions 30a, and the second pixel electrode 20b is formed over the plurality of second column portions 30b. The pixel electrode 20 is formed by the EB deposition method and the patterning. The patterning is performed by, for example, photolithography and etching. In the patterning, a lift-off method may be used instead of etching.

Through the above-described steps, a structure body 110 including the growth substrate 70, the first semiconductor layer 50, the mask layer 40, the plurality of column portions 30, and the plurality of pixel electrodes 20 can be formed.

Note that, although not illustrated in the drawing, when the insulating layer is embedded between the plurality of column portions 30, the insulating layer is formed by, for example, an atomic layer deposition (ALD) method.

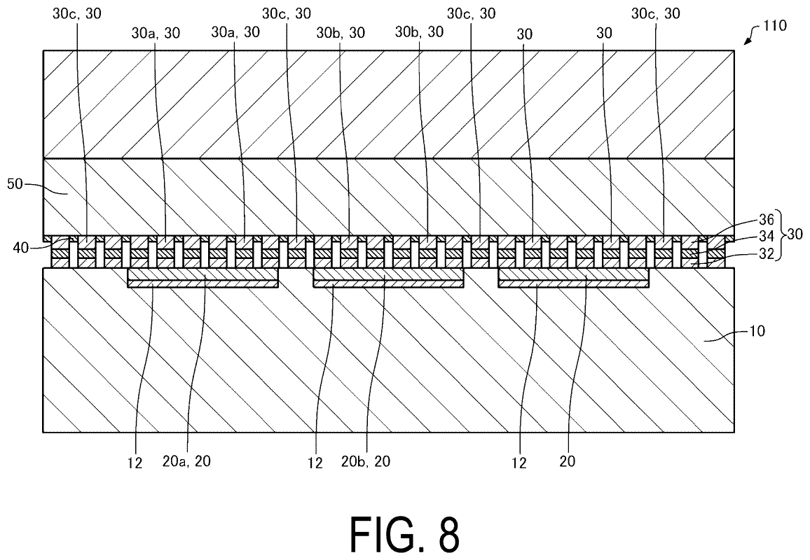

As illustrated in FIG. 8, the structure body 110 is joined to the driving substrate 10 while a side of the structure body 110 close to the pixel electrode 20 faces the driving substrate 10 (Step S5). Specifically, the pad electrode 12 and the pixel electrode 20 are positioned with each other, and the pad electrode 12 and the pixel electrode 20 are joined together. The joining is performed through pressure or heat treatment. For example, the structure body 110 is junction-down mounted to the driving substrate 10. The driving circuit of the driving substrate 10 is formed by injecting impurity ions into an Si substrate, forming an SiO₂ layer, subjecting the pad electrode 12 to the patterning, and the like.

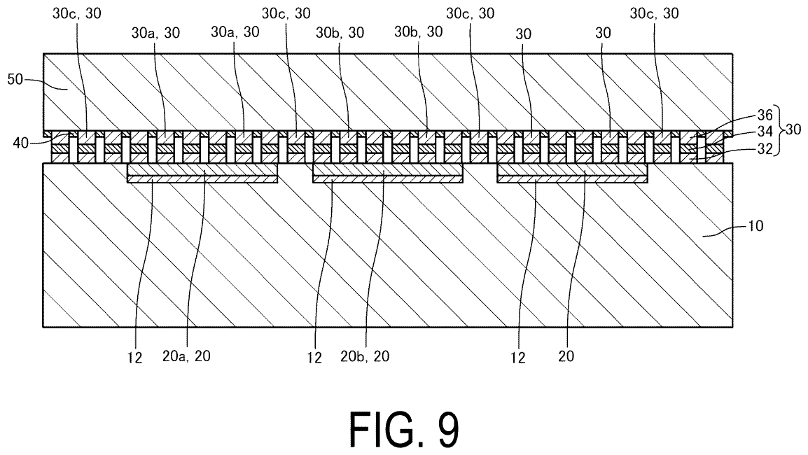

As illustrated in FIG. 9, the growth substrate 70 is removed to expose the first semiconductor layer 50 (Step S6). When the growth substrate 70 is a sapphire substrate, the growth substrate 70 is removed by a laser lift-off method. When the growth substrate 70 is an Si substrate, the growth substrate 70 is removed by polishing or a wet-etching method.

As illustrated in FIG. 1, the first semiconductor layer 50 is reduced in thickness (Step S7). Examples of the method of reducing a thickness include, for example, a chemical mechanical polishing (CMP) method.

Next, the common electrode 60 is formed at the first semiconductor layer 50 (Step S8). The common electrode 60 is formed by, for example, the CVD method, the EB deposition method, or the sputtering method. Then, through wire bonding or the like, which is omitted in illustration, the common electrode 60 and the driving circuit of the driving substrate 10 are electrically coupled to each other.

The light emitting device 100 can be manufactured through the above-described steps.

The method of manufacturing the light emitting device 100 includes forming the first semiconductor layer 50 at the growth substrate 70 being a first substrate, forming the plurality of column portions 30 at the first semiconductor layer 50, forming the first pixel electrode 20a over the plurality of first column portions 30a of the plurality of column portions 30 and forming the second pixel electrode 20b over the plurality of second column portions 30b of the plurality of column portions 30, joining the structure body 110 to the driving substrate 10 being a second substrate while a side of the structure body 110 close to the first pixel electrode 20a and the second pixel electrode 20b faces the driving substrate 10, removing the growth substrate 70 to expose the first semiconductor layer 50, and forming the common electrode 60 at the first semiconductor layer 50. In the step of forming the plurality of column portions 30, the plurality of column portions 30 including the second semiconductor layer 32, the third semiconductor layer 36, and the quantum well layer 34 are formed. Thus, in the method of manufacturing the light emitting device 100, the distance between the first pixel electrode 20a and the second pixel electrode 20b can be reduced.

### 3. Modification Examples of Light Emitting Device

### 3.1. First Modification Example

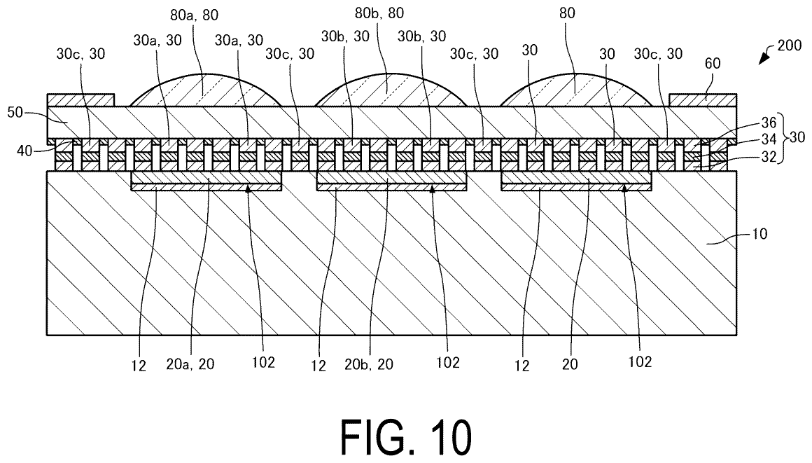

Next, a light emitting device according to a first modification example of the embodiment is described with reference to the drawings. FIG. 10 is a cross-sectional view schematically illustrating a light emitting device 200 according to the first modification example of the embodiment.

In the following description, in the light emitting device 200 according to the first modification example of the embodiment, members having the same functions as the constituent members of the light emitting device 100 according to the embodiment described above are denoted by the same reference signs, and detailed description thereof is omitted. The same applies to a light emitting device according to a second modification example of the embodiment, which is described later.

As illustrated in FIG. 10, the light emitting device 200 is different from the light emitting device 100 described above in that an optical element 80 is included.

The optical element 80 is provided at the first semiconductor layer 50. The optical element 80 is provided on a side of the first semiconductor layer 50 opposite to the driving substrate 10. The first semiconductor layer 50 is provided between the plurality of column portions 30 and the optical element 80.

A plurality of the optical element 80 are provided corresponding to the plurality of pixel electrodes 20. The optical element 80 overlaps with the pixel electrode 20 in plan view. A first optical element 80a of the plurality of optical elements 80 overlaps with the first pixel electrode 20a. A second optical element 80b of the plurality of optical elements 80 overlaps with the second pixel electrode 20b.

For example, the optical element 80 can condense light generated at the quantum well layer 34. The optical element 80 may be a condensing lens. The optical element 80 may be a collimator lens. The plurality of optical elements 80 may configure a micro-lens array.

The light emitting device 200 includes the first optical element 80a being provided on a side of the first semiconductor layer 50 opposite to the driving substrate 10 and overlapping with the first pixel electrode 20a in plan view, and the second optical element 80b being provided on a side of the first semiconductor layer 50 opposite to the driving substrate 10 and overlapping with the second pixel electrode 20b in plan view. Thus, in the light emitting device 200, the first optical element 80a can adjust light generated at the quantum well layer 34 of the first column portion 30a to achieve desired light distribution. Further, the second optical element 80b can adjust light generated at the quantum well layer 34 of the second column portion 30b to achieve desired light distribution.

### 3.2. Second Modification Example

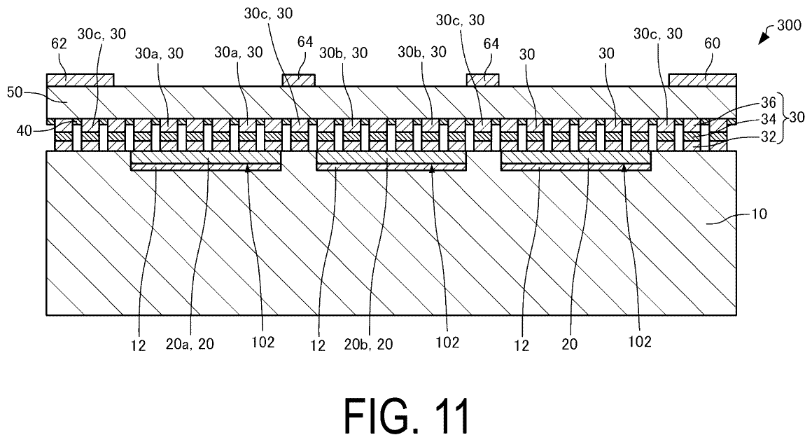

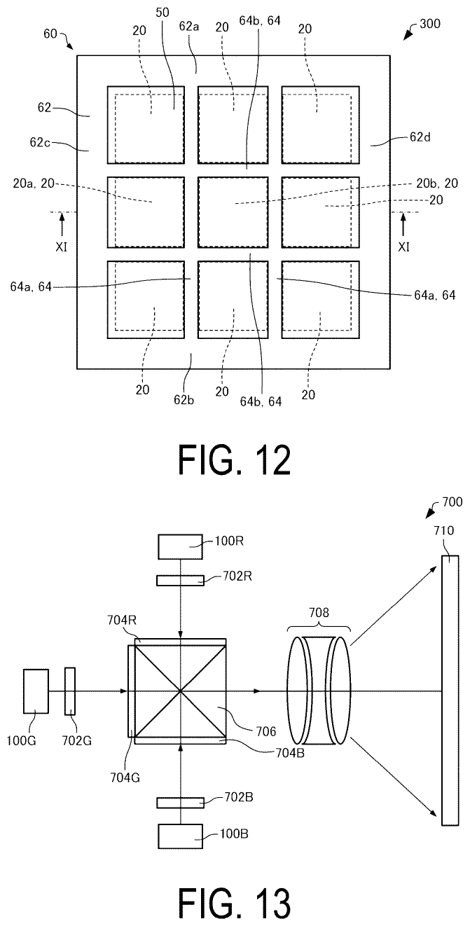

Next, a light emitting device according to a second modification example of the embodiment is described with reference to the drawings. FIG. 11 is a cross-sectional view schematically illustrating a light emitting device 300 according to the second modification example of the embodiment. FIG. 12 is a plan view schematically illustrating the light emitting device 300 according to the second modification example of the embodiment. Note that FIG. 11 is a cross-sectional view taken along the line XI-XI in FIG. 12.

As illustrated in FIG. 11 and FIG. 12, in the light emitting device 300, the shape of the common electrode 60 is different from that in the light emitting device 100 described above. In the light emitting device 300, the common electrode 60 includes a frame portion 62 and an extension portion 64.

As illustrated in FIG. 12, the frame portion 62 surrounds the pixel electrode 20 in plan view. The frame portion 62 includes a first portion 62a, a second portion 62b, a third portion 62c, and a fourth portion 62d. In plan view, the first portion 62a and the second portion 62b are arrayed in a first direction. In plan view, the plurality of pixel electrodes 20 are provided between the first portion 62a and the second portion 62b. In plan view, the third portion 62c and the fourth portion 62d are arrayed in a second direction orthogonal to the first direction. In plan view the plurality of pixel electrodes 20 are provided between the third portion 62c and the fourth portion 62d.

The extension portion 64 is coupled to the frame portion 62. The extension portion 64 extends between the adjacent pixel electrodes 20. For example, a plurality of extension portions 64 are provided. A first extension portion 64a of the plurality of extension portions 64 extends from the first portion 62a to the second portion 62b. In the illustrated example, two first extension portions 64a are provided. One first extension portion 64a of the two first extension portion 64a is provided between the first pixel electrode 20a and the second pixel electrode 20b in plan view. A second extension portion 64b of the plurality of extension portions 64 extends from the third portion 62c to the fourth portion 62d. In the illustrated example, two first extension portions 64a are provided.

In the light emitting device 300, the common electrode 60 includes, in plan view, the frame portion 62 that surrounds the first pixel electrode 20a and the second pixel electrode 20b and the extension portion 64 that extends between the first pixel electrode 20a and the second pixel electrode 20b. Thus, in the light emitting device 300, a distance by which a current of the first semiconductor layer 50 having a relatively high sheet resistance flows can be reduced, and the voltage drop in the first semiconductor layer 50 can be suppressed as compared to a case where the extension portion 64 is not provided. This is particularly advantageous when the first semiconductor layer 50 is thin or the light emitting device has a large area.

### 4. Projector

Next, a projector as an electronic apparatus according to the embodiment is described with reference to the drawings. FIG. 13 is a view schematically illustrating a projector 700 according to the embodiment.

The projector 700 includes, for example, the light emitting device 100 as a light source.

The projector 700 includes a housing, which is not omitted in the drawing, and a red light source 100R, a green light source 100G, and a blue light source 100B that are provided in the housing and emit red light, green light, and blue light, respectively. Note that, for the sake of convenience, in FIG. 13, the red light source 100R, the green light source 100G, and the blue light source 100B are illustrated in a simplified manner.

The projector 700 further includes a first optical element 702R, a second optical element 702G, a third optical element 702B, a first optical modulation device 704R, a second optical modulation device 704G, a third optical modulation device 704B, and a projection device 708 that are provided in the housing. The first optical modulation device 704R, the second optical modulation device 704G, and the third optical modulation device 704B are, for example, transmissive liquid crystal light valves. The projection device 708 is, for example, a projection lens.

The light emitted from the red light source 100R is incident on the first optical element 702R. The light emitted from the red light source 100R is condensed by the first optical element 702R. Note that the first optical element 702R may have a function other than that of condensing light. The second optical element 702G and the third optical element 702B may also have a function other than that of condensing light.

The light condensed by the first optical element 702R is incident on the first optical modulation device 704R. The first optical modulation device 704R modulates the incident light based on image information. Then, the projection device 708 enlarges an image formed by the first optical modulation device 704R and projects the image on a screen 710.

The light emitted from the green light source 100G is incident on the second optical element 702G. The light emitted from the green light source 100G is condensed by the second optical element 702G.

The light condensed by the second optical element 702G is incident on the second optical modulation device 704G. The second optical modulation device 704G modulates the incident light based on image information. Then, the projection device 708 enlarges an image formed by the second optical modulation device 704G and projects the image on the screen 710.

The light emitted from the blue light source 100B is incident on the third optical element 702B. The light emitted from the blue light source 100B is condensed by the third optical element 702B.

The light condensed by the third optical element 702B is incident on the third optical modulation device 704B. The third optical modulation device 704B modulates the incident light based on image information. Then, the projection device 708 enlarges the image formed by the third optical modulation device 704B and projects the image on the screen 710.

The projector 700 further includes a cross dichroic prism 706 that synthesizes the light emitted from the first optical modulation device 704R, the light emitted from the second optical modulation device 704G, and the light emitted from the third optical modulation device 704B and guides the synthesized light to the projection device 708.

Light beams of three colors modulated by the first optical modulation device 704R, the second optical modulation device 704G, and the third optical modulation device 704B are incident on the cross dichroic prism 706. In the cross dichroic prism 706, four right-angle prisms are bonded together, and a dielectric multilayer film that reflects red light and a dielectric multilayer film that reflects blue light are arranged at inner surfaces of the prisms. The light beams of three colors are synthesized by the dielectric multilayer films, and light representing a color image is formed. Then, the synthesized light is projected onto the screen 710 by the projection device 708, and an enlarged image is displayed.

Note that the red light source 100R, the green light source 100G, and the blue light source 100B control the light emitting devices 100 as pixels of a video based on image information, and thus the video may be directly formed without using the first optical modulation device 704R, the second optical modulation device 704G, and the third optical modulation device 704B. The projection device 708 may project the video formed by the red light source 100R, the green light source 100G, and the blue light source 100B onto the screen 710 in an enlarged manner.

Although the transmissive liquid crystal light valve is used as the optical modulation device in the above-described example, a light valve other than the liquid crystal light valve may be used, or a reflective light valve may be used. Examples of such a light valve include a reflective liquid crystal light valve and a digital micro mirror device. A configuration of the projection device is changed as appropriate depending on the type of light valve to be used.

The light source can also be applied to a light source device of a scanning type image display device including a scanning unit which is an image forming device for displaying an image having a desired size on a display surface by scanning a screen with light emitted from the light source.

### 5. Display

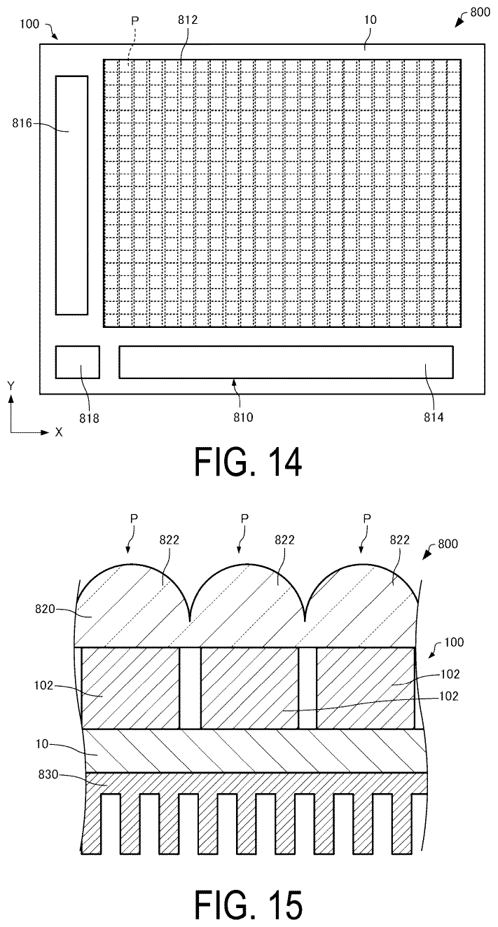

Next, a display as an electronic apparatus according to the embodiment is described with reference to the drawings. FIG. 14 is a plan view schematically illustrating a display 800 according to the embodiment. FIG. 15 is a cross-sectional view schematically illustrating the display 800 according to the embodiment. Note that, in FIG. 14, an X axis and a Y axis are illustrated as two axes orthogonal to each other. Further, for the sake of convenience, in FIG. 14 and FIG. 15, the light emitting device 100 is illustrated in a simplified manner.

The display 800 includes, for example, the light emitting device 100 as a light source.

The display 800 is a display device that displays an image. The image includes those only displaying character information. The display 800 is a self-luminous display. As illustrated in FIG. 14 and FIG. 15, the display 800 includes, for example, a driving circuit 810, a lens array 820, and a heat sink 830.

The driving circuit 810 is provided to the driving substrate 10. The driving circuit 810 drives the light emitting element 102 based on, for example, input image information. For example, the driving substrate 10 includes a display region 812. The driving circuit 810 include a data line driving circuit 814, a scanning line driving circuit 816, and a control circuit 818.

The display region 812 is configured by a plurality of pixels P. In the example illustrated in the drawing, the pixels P are arrayed along the X axis and the Y axis.

Although not illustrated in the drawing, the driving substrate 10 is provided with a plurality of scanning lines and a plurality of data lines. For example, the scanning lines extend along the X axis, and the data lines extend along the Y axis. The scanning lines are coupled to the scanning line driving circuit 816. The data lines are coupled to the data line driving circuit 814. The pixels P are provided corresponding to intersections between the scanning lines and the data lines.

One pixel P includes, for example, one light emitting element 102, one optical element 80, and a pixel circuit (not illustrated). The pixel circuit includes a switching transistor that serves as a switch for the pixel P, a gate of the switching transistor is coupled to the scanning line, and one of a source and a drain thereof is coupled to the data line.

The data line driving circuit 814 and the scanning line driving circuit 816 are circuits that control driving of the light emitting element 102 constituting the pixel P. The control circuit 818 controls display of an image.

Image data is supplied to the control circuit 818 from an upper level circuit. The control circuit 818 supplies various signals based on the image data to the data line driving circuit 814 and the scanning line driving circuit 816.

When the scanning line is selected by activating the scanning signal by the scanning line driving circuit 816, the switching transistor provided in the selected pixel P is turned on. At this time, the data line driving circuit 814 supplies a data signal from the data line to the selected pixel P, and thus the light emitting element 102 of the selected pixel P emits light based on the data signal.

The lens array 820 is configured by a plurality of lenses 822. The heat sink 830 is in contact with the driving substrate 10. The material of the heat sink 830 is, for example, a metal such as copper or aluminum. The heat sink 830 radiates heat generated by the light emitting element 102.

### 6. Head-Mounted Display

### 6.1. Overall Configuration

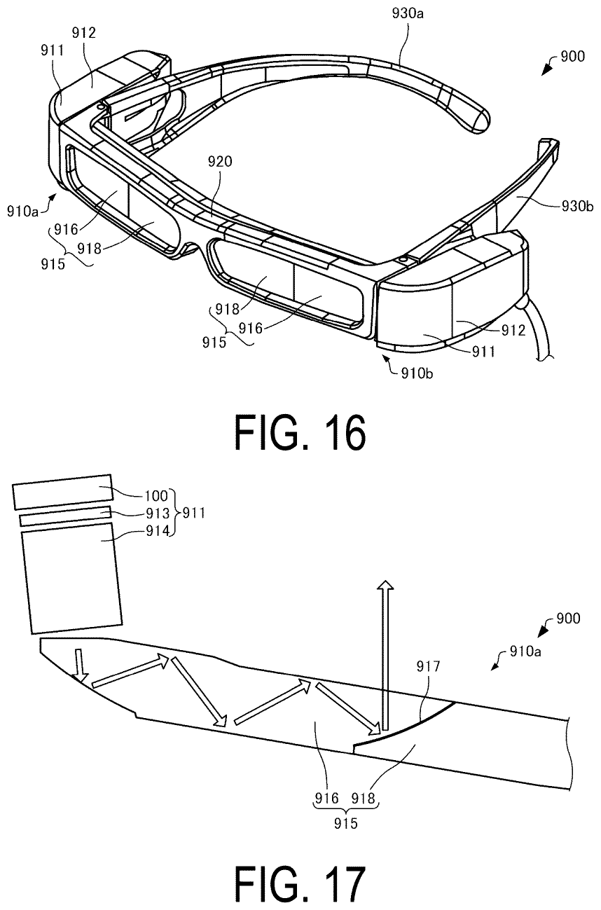

Next, a head-mounted display as an electronic apparatus according to the embodiment is described with reference to the drawings. FIG. 16 is a perspective view schematically illustrating a head-mounted display 900 according to the embodiment.

As illustrated in FIG. 16, the head-mounted display 900 is a head-mounted device that has an outer appearance of an eyewear. The head-mounted display 900 is mounted on a head of a viewer. The viewer is a user who uses the head-mounted display 900. The head-mounted display 900 allows the viewer to visually recognize video light of a virtual image and to visually recognize an external image in a see-through manner.

The head-mounted display 900 includes, for example, a first display unit 910a, a second display unit 910b, a frame 920, a first temple 930a, and a second temple 930b.

The first display unit 910a and the second display unit 910b display images. Specifically, the first display unit 910a displays a virtual image for the right eye of the viewer. The second display unit 910b displays a virtual image for the left eye of the viewer. The display units 910a and 910b include, for example, an image forming device 911 and a light guiding device 915.

The image forming device 911 generates image light. The image forming device 911 includes, for example, an optical system such as a light source and a projection device, and an external member 912. The external member 912 accommodates the light source and the projection device.

The light guiding device 915 covers the front of the eyes of the viewer. The light guiding device 915 guides the video light formed by the image forming device 911 and allows the viewer to visually recognize external light and the video light in an overlapping manner. Note that details of the image forming device 911 and the light guiding device 915 are described below.

The frame 920 supports the first display unit 910a and the second display unit 910b. For example, the frame 920 surrounds the display units 910a and 910b. In the example illustrated in the drawing, the image forming device 911 of the first display unit 910a is attached to one end portion of the frame 920. The image forming device 911 of the second display unit 910b is attached to the other end portion of the frame 920.

The first temple 930a and the second temple 930b extend from the frame 920. In the example illustrated in the drawing, the first temple 930a extends from one end portion of the frame 920. The second temple 930b extends from the other end portion of the frame 920.

The first temple 930a and the second temple 930b are put on the ears of the viewer when the head-mounted display 900 is worn by the viewer. The head of the viewer is positioned between the temples 930a and 930b.

### 6.2. Image Forming Device and Light Guiding Device

FIG. 17 is a view schematically illustrating the image forming device 911 and the light guiding device 915 of the first display unit 910a of the head-mounted display 900. Note that the first display unit 910a and the second display unit 910b have basically the same configuration. Thus, the following description of the first display unit 910a can be applied to the second display unit 910b.

As illustrated in FIG. 17, the image forming device 911 includes, for example, the light emitting device 100 as a light source, an optical modulation device 913, and a projection device 914 for image formation.

The optical modulation device 913 modulates the light incident from the light emitting device 100 based on image information, and emits video light. The optical modulation device 913 is a transmissive liquid crystal light valve. Note that the light emitting device 100 may be a self-luminous light emitting device that emits light based on the image information input. In this case, the optical modulation device 913 is not provided.

The projection device 914 projects the video light emitted from the optical modulation device 913 toward the light guiding device 915. The projection device 914 is, for example, a projection lens. As the lens constituting the projection device 914, a lens having an axially symmetric surface as a lens surface may be used.

The light guiding device 915 is accurately positioned with respect to the projection device 914, for example, by being screwed to a lens barrel of the projection device 914. The light guiding device 915 includes, for example, a video light-guiding member 916 that guides the video light and a see-through member 918 for see-through view.

The video light emitted from the projection device 914 is incident on the video light-guiding member 916. The video light-guiding member 916 is a prism that guides the video light toward the eyes of the viewer. The video light incident on the video light-guiding member 916 is repeatedly reflected on the inner surface of the video light-guiding member 916, and is then reflected by a reflective layer 917 to be emitted from the video light-guiding member 916. The video light emitted from the video light-guiding member 916 reaches the eyes of the viewer. The reflective layer 917 is configured by, for example, a metal or a dielectric multilayer film. The reflective layer 917 may be a half mirror.

The see-through member 918 is adjacent to the video light-guiding member 916. The see-through member 918 is fixed to the video light-guiding member 916. The outer surface of the see-through member 918 is continuous with, for example, the outer surface of the video light-guiding member 916. The viewer sees external light through the see-through member 918. The video light-guiding member 916 also has a function of making the viewer see external light therethrough, in addition to the function of guiding video light. Note that the head-mounted display 900 may be configured not to allow the viewer to see external light therethrough.

The light emitting devices according to the embodiments described above can be used for devices other than the projector, the display, and the head-mounted display. The light emitting device according to the above-described embodiment is used for, for example, indoor and outdoor lighting, a laser printer, a scanner, a sensing device using light, an electronic view finder (EVF), a wearable display such as a smart watch, an in-vehicle light, and an in-vehicle head-up display.

The embodiment and the modification examples described above are merely examples, and are not intended as limiting. For example, each embodiment and each modification example can also be combined together as appropriate.

The present disclosure includes configurations that are substantially identical to the configurations described in the embodiment, for example, configurations with identical functions, methods and results, or with identical objects and effects. Also, the present disclosure includes configurations obtained by replacing non-essential portions of the configurations described in the embodiment. In addition, the present disclosure includes configurations having the same operations and effects or can achieve the same objects as the configurations described in the embodiment. Further, the present disclosure includes configurations obtained by adding known techniques to the configurations described in the embodiment.

The following contents are derived from the embodiment and the modification examples described above.

According to one aspect, a light emitting device includes a substrate, a plurality of column portions, a first semiconductor layer of a first conductivity type, the first semiconductor layer being provided to overlap with the plurality of column portions, a first pixel electrode being provided between a plurality of first column portions of the plurality of column portions and the substrate, a second pixel electrode being provided between a plurality of second column portions of the plurality of column portions and the substrate and being separated from the first pixel electrode, and a common electrode being provided on a side of the first semiconductor layer opposite to the substrate, wherein each of the plurality of column portions includes a second semiconductor layer of a second conductivity type different from the first conductivity type, a third semiconductor layer of the first conductivity type, the third semiconductor layer being provided between the first semiconductor layer and the second semiconductor layer, and a quantum well layer being provided between the second semiconductor layer and the third semiconductor layer.

According to the light emitting device, the distance between the first pixel electrode and second pixel electrode can be reduced.

In the light emitting device according to the one aspect, the common electrode may not overlap with the first pixel electrode and the second pixel electrode in plan view.

According to the light emitting device, the common electrode can lower the possibility of absorbing light generated at the quantum well layer.

In the light emitting device according to the one aspect, the common electrode may include, in plan view, a frame portion surrounding the first pixel electrode and the second pixel electrode, and an extension portion being provided between the first pixel electrode and the second pixel electrode.

According to the light emitting device, a distance by which a current of the first semiconductor layer having a relatively high sheet resistance flows can be reduced, and the voltage drop in the first semiconductor layer can be suppressed.

The light emitting device according to the one aspect may include a first optical element being provided on a side of the first semiconductor layer opposite to the substrate and overlapping with the first pixel electrode in plan view, and a second optical element being provided on a side of the first semiconductor layer opposite to the substrate and overlapping with the second pixel electrode in plan view.

According to the light emitting device, the first optical element can adjust light generated at the quantum well layer of the first column portion to achieve desired light distribution. Further, the second optical element can adjust light generated at the quantum well layer of the second column portion to achieve desired light distribution.

In the light emitting device according to the one aspect, the material of the first pixel electrode and the second pixel electrode may be metal.

According to the light emitting device, the first pixel electrode can reflect light generated at the quantum well layer of the first column portion. Further, the second pixel electrode can reflect light generated at the quantum well layer of the second column portion.

In the light emitting device according to the one aspect, a third column portion of the plurality of column portions may be provided between the first pixel electrode and the second pixel electrode in plan view.

According to the light emitting device, the third column portion that is provided between the first pixel electrode and the second pixel electrode in plan view is not removed, and hence the structure of the light emitting device can be simplified.

An electronic apparatus according to one aspect includes the light emitting device according to the one aspect.

According to one aspect, a method of manufacturing a light emitting device includes forming a first semiconductor layer of a first conductive type at a first substrate, forming a plurality of column portions at the first semiconductor layer, forming a first pixel electrode over a plurality of first column portions of the plurality of column portions and forming a second pixel electrode over a plurality of second column portions of the plurality of column portions, joining, to a second substrate, a structure body including the first substrate, the first semiconductor layer, the plurality of column portions, the first pixel electrode, and the second pixel electrode while a side of the structure body that is close to the first pixel electrode and the second pixel electrode faces the second substrate, removing the first substrate to expose the first semiconductor layer, and forming a common electrode at the first semiconductor layer, wherein, during the formation of the plurality of column portions, the plurality of column portions are formed, the plurality of column portions including a second semiconductor layer of a second conductivity type different from the first conductivity type, a third semiconductor layer of the first conductivity type, and a quantum well layer being provided between the second semiconductor layer and the third semiconductor layer.

According to the method of manufacturing a light emitting device, a light emitting device that can reduce the distance between the first pixel electrode and second pixel electrode can be manufactured.

What is claimed is:

1. A light emitting device, comprising:
a substrate;
a plurality of column portions;
a first semiconductor layer of a first conductivity type, the first semiconductor layer being provided to overlap with the plurality of column portions;
a first pixel electrode being provided between a plurality of first column portions of the plurality of column portions and the substrate;
a second pixel electrode being provided between a plurality of second column portions of the plurality of column portions and the substrate and being separated from the first pixel electrode; and
a common electrode being provided on a side of the first semiconductor layer opposite to the substrate, wherein
each of the plurality of column portions includes:
a second semiconductor layer of a second conductivity type different from the first conductivity type;
a third semiconductor layer of the first conductivity type, the third semiconductor layer being provided between the first semiconductor layer and the second semiconductor layer; and
a quantum well layer being provided between the second semiconductor layer and the third semiconductor layer.

2. A light emitting device according to claim 1, wherein
the common electrode does not overlap with the first pixel electrode and the second pixel electrode in a plan view.

3. A light emitting device according to claim 2, wherein
the common electrode includes, in the plan view:
a frame portion surrounding the first pixel electrode and the second pixel electrode; and
an extension portion being provided between the first pixel electrode and the second pixel electrode.

4. A light emitting device according to claim 1, further comprising:
a first optical element being provided on a side of the first semiconductor layer opposite to the substrate and overlapping with the first pixel electrode in a plan view; and
a second optical element being provided on a side of the first semiconductor layer opposite to the substrate and overlapping with the second pixel electrode in the plan view.

5. A light emitting device according to claim 1, wherein
a material of the first pixel electrode and the second pixel electrode is metal.

6. A light emitting device according to claim 1, wherein
a third column portion of the plurality of column portions is provided between the first pixel electrode and the second pixel electrode in a plan view.

7. An electronic apparatus, comprising the light emitting device according to claim 1.

8. A method of manufacturing a light emitting device, the method comprising:
forming a first semiconductor layer of a first conductive type at a first substrate;
forming a plurality of column portions at the first semiconductor layer;
forming a first pixel electrode over a plurality of first column portions of the plurality of column portions and forming a second pixel electrode over a plurality of second column portions of the plurality of column portions;
joining, to a second substrate, a structure body including the first substrate, the first semiconductor layer, the plurality of column portions, the first pixel electrode, and the second pixel electrode while a side of the structure body that is close to the first pixel electrode and the second pixel electrode faces the second substrate;
removing the first substrate to expose the first semiconductor layer; and
forming a common electrode at the first semiconductor layer, wherein
during the formation of the plurality of column portions, the plurality of column portions are formed, the plurality of column portions including a second semiconductor layer of a second conductivity type different from the first conductivity type, a third semiconductor layer of the first conductivity type, and a quantum well layer being provided between the second semiconductor layer and the third semiconductor layer.
